(19) United States
(12) Patent Application Publication
(10) Pub. No.: US 2024/0293871 A1
(43) Pub. Date: Sep. 5, 2024

(54) COATED TOOL AND CUTTING TOOL

(71) Applicant: KYOCERA CORPORATION, Kyoto-shi, Kyoto (JP)

(72) Inventors: Kei YOSHIMI, Satsumasendai-shi, Kagoshima (JP); Satoshi MORI, Satsumasendai-shi, Kagoshima (JP)

(21) Appl. No.: 18/574,747

(22) PCT Filed: Jul. 7, 2022
(86) PCT No.: PCT/JP2022/026964

§ 371 Date: Dec. 28, 2023

(30) Foreign Application Priority Data
Jul. 30, 2021 (JP) 2021-126271

(51) Int. Cl. B23B 27/14; C23C 14/06; C23C 14/16

(52) U.S. Cl. CPC B23B 27/14; C23C 14/0641; C23C 14/16

(57) ABSTRACT

A coated tool according to the present disclosure includes a base body made of a WC-based cemented carbide containing WC particles as a hard phase component and Co as a main component of a binding phase, and a first coating layer located on the base body. In an interface region between the base body and the first coating layer in a cross section perpendicular to a surface of the base body, when a maximum value (atm %) of Ti obtained by elemental analysis in a transverse direction from the first coating layer to the WC particle is defined as a Ti(WC) value, a maximum value (atm %) of Ti obtained by elemental analysis in a transverse direction from the first coating layer to the binding phase is defined as a Ti(Co) value, and a ratio (Ti(Co) value/Ti(WC) value) of the Ti(WC) value and the Ti (Co) value is defined as a Ti(Co/WC) ratio, the Ti(Co/WC) ratio is 0.8 or less.

### CROSS-REFERENCE TO RELATED APPLICATIONS

This application is national stage application of International Application No. PCT/JP2022/026964, filed on Jul. 7, 2022, which claims the benefit of priority from Japanese Patent Application No. 2021-126271, filed on Jul. 30, 2021.

### TECHNICAL FIELD

The present disclosure relates to a coated tool and a cutting tool.

### BACKGROUND OF INVENTION

As a tool used for cutting processing such as turning processing or milling processing, a coated tool is known in which a surface of a base body made of cemented carbide, cermet, ceramic, or the like is coated with a coating layer to improve wear resistance, and the like.

### CITATION LIST

### Patent Literature

Patent Document 1: WO2019/146710
Patent Document 2: JP 2017-193004 A

### SUMMARY

A coated tool according to an aspect of the present disclosure includes a base body made of WC-based cemented carbide containing WC particles as a hard phase component and Co as a main component of a binding phase, and a first coating layer located on the base body. The first coating layer is made of at least one element selected from the group consisting of Al, Cr, Si, Group 4 elements, Group 5 elements, and Group 6 elements, and at least one element selected from the group consisting of C and N. In an interface region between the base body and the first coating layer in a cross section perpendicular to a surface of the base body, when a maximum value (atm %) of Ti obtained by elemental analysis in a transverse direction from the first coating layer to the WC particle is defined as a Ti(WC) value, a maximum value (atm %) of Ti obtained by elemental analysis in a transverse direction from the first coating layer to the binding phase is defined as a Ti(Co) value, and a ratio (Ti(Co) value/Ti(WC) value) of the Ti(WC) value and the Ti (Co) value is defined as a Ti(Co/WC) ratio, the Ti(Co/WC) ratio is 0.8 or less.

### BRIEF DESCRIPTION OF THE DRAWINGS

FIG. 1 is a perspective view illustrating an example of a coated tool according to an embodiment.

FIG. 2 is a side sectional view illustrating the example of the coated tool according to the embodiment.

FIG. 3 is a sectional view illustrating an example of a coating layer according to the embodiment.

FIG. 4 is a schematic enlarged view of a portion H illustrated in FIG. 3.

FIG. 5 is a schematic enlarged view of an interface region between a base body and a first coating layer.

FIG. 6 is a front view illustrating an example of a cutting tool according to the embodiment.

FIG. 7 is a table summarizing manufacturing conditions of intermediate layers included in Samples No. 1 to No. 20.

FIG. 8 is a table summarizing an average composition of the first coating layer, presence or absence of Ti in the intermediate layer, a Ti(Co/WC) ratio, and an average layer thickness of a Ti-containing layer on WC particles of Samples No. 1 to No. 20.

FIG. 9 is a table summarizing results of an oxidation test, a wear test, and a peeling test on Samples No. 1 to No. 20.

FIG. 10 is a scanning transmission electron microscope image of the coated tool according to an example.

FIG. 11 is a WC mapping image of the coated tool according to the example.

FIG. 12 is a Co mapping image of the coated tool according to the example.

FIG. 13 is a Ti mapping image of the coated tool according to the example.

FIG. 14 is a view illustrating an extraction range on WC and an extraction range on Co.

FIG. 15 is a graph showing measurement results of amounts of Ti within the extraction range on WC and the extraction range on Co.

### DESCRIPTION OF EMBODIMENTS

The following is a detailed description of a coated tool and a cutting tool according to the present disclosure (hereinafter referred to as “embodiments”) with reference to the drawings. Note that the coated tool and the cutting tool according to the present disclosure are not limited by the embodiments. Embodiments can be appropriately combined so as not to contradict each other in terms of processing content. In the following embodiments, the same portions are denoted by the same reference signs, and overlapping explanations are omitted.

In the embodiments described below, expressions such as “constant”, “orthogonal”, “perpendicular”, and “parallel” may be used, but these expressions do not need to be exactly “constant”, “orthogonal”, “perpendicular”, and “parallel”. In other words, each of the above-described expressions allows for deviations in, for example, manufacturing accuracy, positioning accuracy, and the like.

In the related art described above, there is room for further improvement in terms of improving the adhesion between the coating layer and the base body.

### Coated Tool

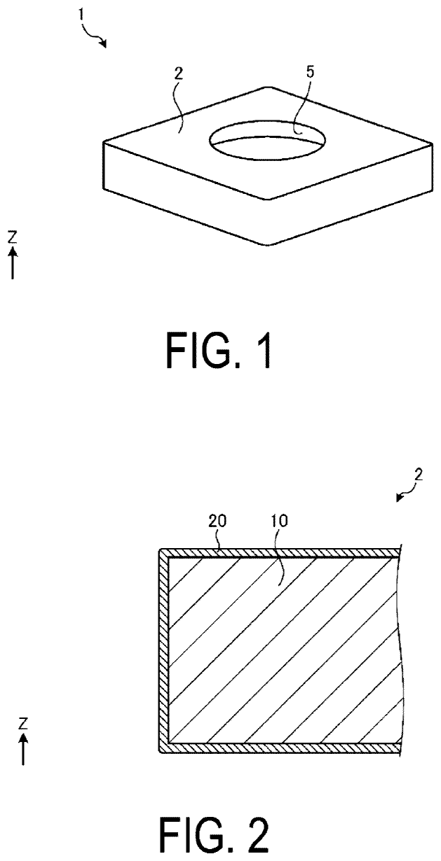

FIG. 1 is a perspective view illustrating an example of a coated tool according to an embodiment. FIG. 2 is a side sectional view illustrating an example of the coated tool 1 according to the embodiment. As illustrated in FIG. 1, a coated tool 1 according to the embodiment includes a tip body 2.

### Tip Body 2

The tip body 2 has a hexagonal shape in which a shape of an upper surface and a lower surface (a surface intersecting the Z-axis illustrated in FIG. 1) is a parallelogram.

One corner portion of the tip body 2 functions as a cutting edge portion. The cutting edge portion has a first surface (for example, an upper surface) and a second surface (for example, a side surface) connected to the first surface. In the embodiment, the first surface functions as a “rake face” for scooping chips generated by cutting, and the second surface functions as a “flank face”. A cutting edge is located on at least a part of a ridge line where the first surface and the second surface intersect with each other, and the coated tool 1 cuts a work material through application of the cutting edge to the work material.

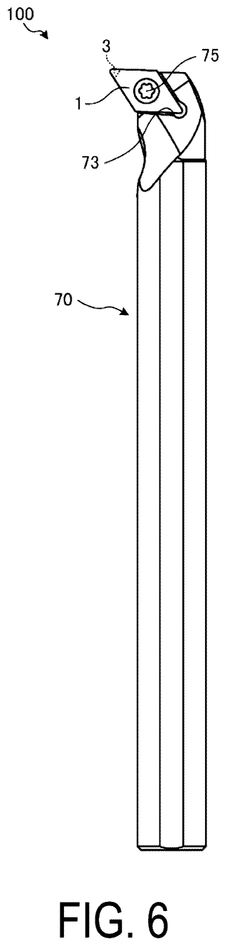

A through hole 5 that vertically penetrates the tip body 2 is located in the center portion of the tip body 2. A screw 75 for attaching the coated tool 1 to a holder 70 described below is inserted into the through hole 5 (see FIG. 6).

As illustrated in FIG. 2, the tip body 2 has a base body 10, and a coating layer 20.

Base Body 10

The base body 10 is formed of, for example, cemented carbide. The cemented carbide contains tungsten (W), specifically, tungsten carbide (WC). Further, the cemented carbide may contain nickel (Ni) or cobalt (Co). Specifically, the base body 10 is made of WC-based cemented carbide containing WC particles as a hard phase component and Co as a main component of a binding phase.

Coating Layer 20

The coating layer 20 is coated on the base body 10 for the purpose of, for example, improving wear resistance, heat resistance, and the like of the base body 10. In the example in FIG. 2, the coating layer 20 entirely coats the base body 10. The coating layer 20 may be located at least on the base body 10. When the coating layer 20 is located on a first surface (here, an upper surface) of the base body 10, the first surface has high wear resistance and heat resistance. When the coating layer 20 is located on a second surface (here, a side surface) of the base body 10, the second surface has high wear resistance and heat resistance.

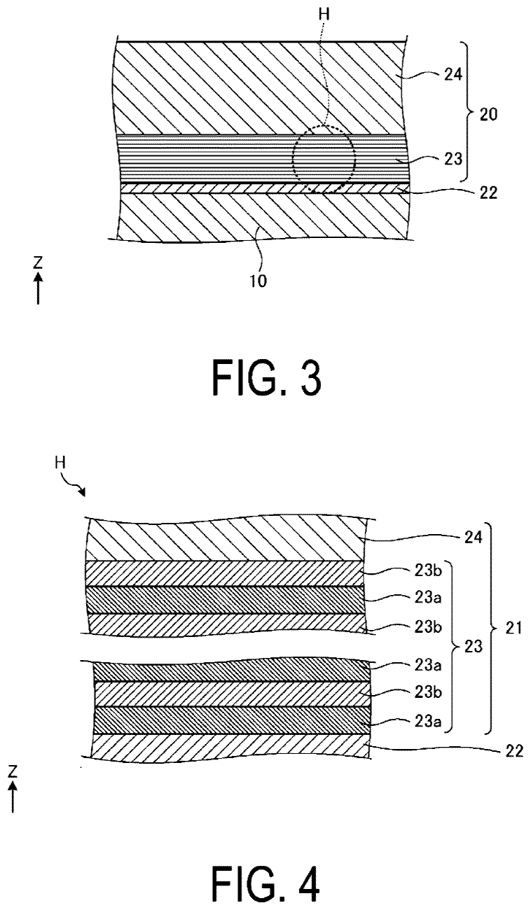

Here, a specific configuration of the coating layer 20 will be described with reference to FIGS. 3 and 4. FIG. 3 is a sectional view illustrating an example of the coating layer 20 according to the embodiment. FIG. 4 is a schematic enlarged view of a portion H illustrated in FIG. 3.

As illustrated in FIG. 3, the coating layer 20 includes a first coating layer 23 located on the intermediate layer 22, and a second coating layer 24 located on the first coating layer 23.

The first coating layer 23 is made of at least one element selected from the group consisting of Al, Cr, Si, Group 4 elements, Group 5 elements, and Group 6 elements, and at least one element selected from the group consisting of C and N.

Specifically, the first coating layer 23 may include Al, Cr, Si, and N. That is, the first coating layer 23 may be an AlCrSiN layer containing AlCrSiN, which is a nitride of Al, Cr and Si. Note that the expression “AlCrSiN” means that Al, Cr, Si, and N are present at an arbitrary ratio, and does not necessarily mean that Al, Cr, Si, and N are present at a ratio of 1:1:1:1.

When the first coating layer 23 containing the metal (for example, Ti) included in the intermediate layer 22 is located on the intermediate layer 22, the adhesion between the intermediate layer 22 and the coating layer 20 is high. This makes it difficult for the coating layer 20 to peel off from the intermediate layer 22, so the durability of the coating layer 20 is high.

As illustrated in FIG. 4, the first coating layer 23 includes a plurality of first layers 23a and a plurality of second layers 23b. The first coating layer 23 has a striped configuration in which the first layer 23a and the second layer 23b are alternately stacked in a thickness direction. The second layer 23b is formed on the first layer 23a.

The thickness of each of the first layer 23a and the second layer 23b may be 50 nm or less. Since the first layer 23a and the second layer 23b formed to be thin have small residual stresses and are less likely to cause peeling, cracking, or the like, the durability of the coating layer 20 is enhanced.

The second coating layer 24 may include Ti, Si, and N. That is, the second coating layer 24 may be a nitride layer (TiSiN layer) containing Ti and Si. Note that the expression “TiSiN layer” means that Ti, Si, and N are present at an arbitrary ratio, and does not necessarily mean that Ti, Si, and N are present at a ratio of 1:1:1.

As a result, for example, when a coefficient of friction of the second coating layer 24 is low, the welding resistance of the coated tool 1 can be improved. For example, when the hardness of the second coating layer 24 is high, the wear resistance of the coated tool 1 can be improved. For example, when an oxidation start temperature of the second coating layer 24 is high, the oxidation resistance of the coated tool 1 can be improved.

The second coating layer 24 may have a striped structure in which at least two layers are located in the thickness direction. Each layer included in the striped structure of the second coating layer 24 may contain, for example, Ti, Si, and N. In this case, in the second coating layer 24, the content of Ti (hereinafter referred to as “Ti content”), the content of Si (hereinafter referred to as “Si content”), and the content of N (hereinafter referred to as “N content”) may each repeatedly increase and decrease along the thickness direction of the second coating layer 24. A sum of Ti and Si of the metal elements contained in the second coating layer 24 may be 98 atomic % or more. The second coating layer 24 may include a third layer and a fourth layer alternately located in the thickness direction.

Method for Manufacturing Coating Layer

The coating layer 20 may be formed by, for example, a physical vapor deposition method.

Examples of the physical vapor deposition method may include an ion plating method and a sputtering method. For example, when the coating layer is formed by an ion plating method, the coating layer may be fabricated by the following method.

First, an example of a method for fabricating the first coating layer 23 by an ion plating method will be described. First, as an example, each metal target of Cr, Si, and Al, a composite alloy target, or a sintered body target is prepared.

Next, the target serving as a metal source is vaporized and ionized by arc discharge, glow discharge, or the like. The ionized metal is reacted with a nitrogen (N₂) gas of a nitrogen source and deposited on the surface of the base body. The AlCrSiN layer can be formed by the procedure described above.

In the above procedure, the temperature of the base body may be set to 500 to 550° C., the nitrogen gas pressure may be set to 1.0 to 6.0 Pa, a direct-current bias voltage of −50 to −200 V may be applied to the base body, and the arc discharge current may be set to 100 to 200 A.

A composition of the first coating layer 23 can be adjusted by independently controlling the voltage and current values at the time of arc discharge and glow discharge applied to the aluminum metal target, the chromium metal target, the aluminum-silicon composite alloy target, and the chromium-silicon composite alloy target, for each target. The composition of the coating layer can be adjusted by controlling the coating time and the atmospheric gas pressure. In an example of the embodiment, an amount of ionization of the target metal can be changed by changing the voltage and current values at the time of arc discharge and glow discharge. By periodically changing the current value at the time of arc discharge or glow discharge for each target, the amount of ionization of the target metal can be periodically changed. The amount of ionization of the target metal can be periodically changed by periodically changing the current value at the time of arc discharging or glow discharging of the target at intervals of 0.01 to 0.5 minutes. Consequently, in the thickness direction of the coating layer, the content ratio of each metal element can be changed in each period.

When carrying out the above procedure, the composition of Al, Si and Cr is changed so that the amounts of Al and Si are decreased and the amount of Cr is increased, and then the composition of Al, Si and Cr is changed so that the amounts of Al and Si are increased and the amount of Cr is decreased, whereby the first coating layer 23 including the first layer 23a and the second layer 23b can be fabricated.

An example of a method for manufacturing the second coating layer 24 that is a TiSiN layer will be described.

As with the first coating layer 23, the second coating layer 24 may also be formed by the physical vapor deposition method. As an example, first, a Ti metal target and a Ti—Si composite alloy target are prepared. Then, the voltage and current values at the time of arc discharge and glow discharge applied to the prepared targets are independently controlled for each target, whereby the second coating layer 24 having a striped structure can be fabricated.

In the above procedure, the temperature of the base body may be 500 to 600° C., the nitrogen gas pressure may be set to 1.0 to 6.0 Pa, the direct-current bias voltage of −50 to −200 V may be applied to the base body, the arc discharge current may be set to 100 to 200 A, and the change cycle of the arc current may be set to 0.01 to 0.5 minutes.

### Intermediate Layer 22

An intermediate layer 22 may be located between the base body 10 and the coating layer 20. Specifically, the intermediate layer 22 has one surface (here, a lower surface) in contact with the upper surface of the base body 10 and another surface (here, an upper surface) in contact with the lower surface of the coating layer 20 (first coating layer 23).

The intermediate layer 22 has higher adhesion to the base body 10 than to the coating layer 20. Examples of a metal element having such characteristics include Zr, Hf, V, Nb, Ta, Cr, Mo, W, Al, Si, Y, and Ti. The intermediate layer 22 contains at least one metal element among the above-described metal elements. For example, the intermediate layer 22 may contain Ti. Note that Si is a metalloid element, but in the present specification, it is assumed that a metalloid element is also included in the metal element.

When the intermediate layer 22 contains Ti, the content of Ti in the intermediate layer 22 may be 1.5 atomic % or more. For example, the content of Ti in the intermediate layer 22 may be 2.0 atomic % or more.

The intermediate layer 22 may contain metal element components other than the above-described metal elements (Zr, Hf, V, Nb, Ta, Cr, Mo, W, Al, Si, Y, and Ti). However, from the standpoint of adhesion to the base body 10, the intermediate layer 22 may contain at least 95 atomic % or more of the metal elements in a combined amount. More preferably, the intermediate layer 22 may contain 98 atomic % or more of the metal elements in a combined amount. Note that the ratio of the metal components in the intermediate layer 22 can be identified by, for example, analysis using an energy dispersive X-ray spectrometer (EDS) attached to a scanning transmission electron microscope (STEM).

As described above, in the coated tool 1 according to the embodiment, by providing the intermediate layer 22 having higher wettability with the base body 10 than the coating layer 20 between the base body 10 and the coating layer 20, the adhesion between the base body 10 and the coating layer 20 can be improved. Note that since the intermediate layer 22 also has high adhesion to the coating layer 20, the coating layer 20 is less likely to peel off from the intermediate layer 22.

Note that a thickness of the intermediate layer 22 may be, for example, 0.1 nm or greater and less than 20.0 nm.

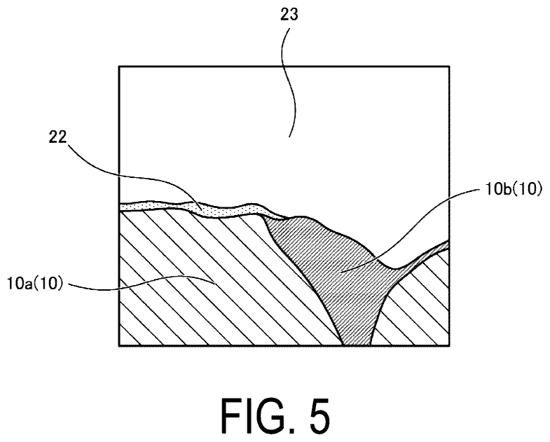

FIG. 5 is a schematic enlarged view of an interface region between the base body 10 and the first coating layer 23. FIG. 5 illustrates an interface region between the base body 10 and the first coating layer 23 in a cross section perpendicular to a surface of the base body 10.

As illustrated in FIG. 5, the intermediate layer 22 located in the interface region between the base body 10 and the first coating layer 23 is located mostly on the WC particles 10a among the WC particles 10a and the binding phase 10b included in the base body 10. Specifically, a maximum value (atm %) of Ti obtained by elemental analysis in a

transverse direction from the first coating layer 23 to the WC particle 10a is defined as a Ti(WC) value, and a maximum value (atm %) of Ti obtained by elemental analysis in a transverse direction from WC from the first coating layer 23 to the binding phase 10b is defined as a Ti(Co) value.

A ratio (Ti(Co) value/Ti(WC) value) of the Ti(WC) value and the Ti(Co) value is defined as a Ti(Co/WC) ratio. In this case, in the coated tool 1 according to the embodiment, the Ti(Co/WC) ratio is 0.8 or less.

In the related art, the first coating layer made of at least one element selected from the group consisting of Al, Cr, Si, Group 4 elements, Group 5 elements, and Group 6 elements, and at least one element selected from the group consisting of C and N has room for improvement in terms of improving the adhesion to the WC particles. On the other hand, Ti has good adhesion to both the first coating layer and the WC particles. For this reason, by introducing the intermediate layer 22 containing Ti between the first coating layer 23 and the WC particles 10a as in the coated tool 1 according to the embodiment, the adhesion between the base body 10 and the first coating layer 23 can be improved.

The intermediate layer 22 having the above-described configuration can be obtained by, for example, the following manufacturing method.

The base body is heated under a reduced pressure environment of 8×10⁻³ to 1× 10-4 Pa to set a surface temperature to 500 to 600°° C. Next, an argon gas is introduced as an atmospheric gas, and the pressure is maintained at 3.0 Pa. Next, a bias voltage is set to −400 V, and an argon bombardment treatment is performed for 11 minutes (Ar bombardment pretreatment). Next, the pressure is reduced to 0.1 Pa, an arc current of 100 to 200 A is applied to a Ti metal evaporation source, and a treatment is performed for 0.3 minutes to form a Ti-containing layer as an intermediate layer on the surface of the base body (Ti-containing-layer film forming treatment). Thereafter, argon gas is introduced as an atmospheric gas, the pressure is maintained at 3.0 Pa, the bias voltage is set to −200 V, and argon bombardment treatment is performed for 1 minute (Ar bombardment post-treatment).

Argon Bombardment Pretreatment Conditions
(1) Bias voltage: −400 V
(2) Pressure: 3 Pa
(3) Treatment time: 11 minutes

Film Forming Conditions 1 of Ti-Containing Layer
(1) Arc current: 100 to 200 A
(2) Bias voltage: −380 to −430 V
(3) Pressure: 0.1 Pa
(4) Treatment time: 0.3 minutes

Argon Bombardment Post-treatment Conditions 1
(1) Bias voltage: −200 V
(2) Pressure: 3 Pa
(3) Treatment time: 1 minute

Note that the Ti-containing layer may contain other metal elements by diffusion, for example. The Ti-containing layer may contain 50 to 98 atomic % of a metal element other than Ti.

The adhesion between the binding phase containing Co and Ti is poor. For this reason, when the amount of Ti located on the binding phase containing Co is as small as possible, the overall adhesion between the base body and the coating layer is improved. Therefore, by adopting a configuration in which a larger amount of Ti is located on the WC particles 10a of the WC particles 10a and the binding phase 10b included in the base body 10 as in the coated tool 1 according to the embodiment, it is possible to improve the adhesion between the base body 10 and the first coating layer 23, whereby it is possible to improve wear resistance and fracture resistance of the coated tool 1.

At least a portion of the binding phase 10b may be in contact with the first coating layer 23 in the cross section perpendicular to the surface of the base body 10.

The adhesion between the first coating layer made of at least one element selected from the group consisting of Al, Cr, Si, Group 4 elements, Group 5 elements, and Group 6 elements and the binding phase containing Co is better than the adhesion between the binding phase containing Co and Ti. For this reason, when at least a portion of the binding phase 10b is in contact with the first coating layer 23, the adhesion between the base body 10 and the first coating layer 23 can be further improved, and the wear resistance and the fracture resistance of the coated tool 1 can be further improved.

The configuration in which at least a portion of the binding phase 10b is in contact with the first coating layer 23 can be manufactured under the following conditions, for example.

Argon Bombardment Pretreatment Conditions
(1) Bias voltage: −400 V
(2) Pressure: 3 Pa or lower
(3) Treatment time: 11 minutes

Film Forming Conditions 2 of Ti-Containing Layer
(1) Arc current: 130 A or higher and 180 A or lower
(2) Bias voltage: −390 V or higher and −410V or lower
(3) Pressure: 0.1 Pa
(4) Treatment time: 0.3 minutes

Argon Bombardment Post-treatment Conditions 2
(1) Bias voltage: −200 V
(2) Pressure: 3 Pa
(3) Treatment time: 1 minute

The film forming conditions 2 of the Ti-containing layer and the argon bombardment treatment conditions 2 are alternately repeated one or more times.

A thickness of a region containing Ti on the WC particles 10a in the interface region, i.e., the intermediate layer 22 on the WC particles 10a may be 1 nm or greater and 15 nm or less.

When the thickness of the intermediate layer 22 is 1 nm or greater, the adhesion effect between the first coating layer 23 and the WC particles 10a is further exhibited, and when the thickness of the intermediate layer 22 is 15 nm or less, the occurrence and propagation of cracks from the intermediate layer 22 are suppressed. Therefore, by setting the thickness of the intermediate layer 22 on the WC particles 10a to 1 nm or greater and 15 nm or less, the adhesion between the base body 10 and the first coating layer 23 can be further improved, and the wear resistance and the fracture resistance of the coated tool 1 can be further improved.

The intermediate layer 22 in which the thickness of the intermediate layer 22 on the WC particles 10a is 1 nm or greater and 15 nm or less can be manufactured according to following conditions.

Argon Bombardment Pretreatment Conditions
(1) Bias voltage: −400 V
(2) Pressure: 3 Pa or lower
(3) Treatment time: 11 minutes

Film Forming Conditions 3 of Ti-Containing Layer
(1) Arc current: 100 A or more, 180 A or lower
(2) Bias voltage: −400 V
(3) Pressure: 0.1 Pa
(4) Treatment time: 0.3 minutes

Argon Bombardment Post-treatment Conditions 3
(1) Bias voltage: −200 V
(2) Pressure: 3 Pa
(3) Treatment time: 1 minute

The film forming conditions 3 of the Ti-containing layer and the argon bombardment treatment conditions 3 are alternately repeated one or more times and 20 times or less. Cutting Tool

Next, a configuration of a cutting tool including the coated tool 1 described above will be described with reference to FIG. 6. FIG. 6 is a front view illustrating an example of a cutting tool according to the embodiment.

As illustrated in FIG. 6, a cutting tool 100 according to the embodiment includes the coated tool 1 and a holder 70 for fixing the coated tool 1.

The holder 70 is a rod-like member extending from a first end (upper end in FIG. 6) toward a second end (lower end in FIG. 6). The holder 70 is made of, for example, steel or cast iron. In particular, it is preferable to use steel having high toughness among these members.

The holder 70 has a pocket 73 at an end portion on the first end side. The pocket 73 is a portion in which the coated tool 1 is mounted, and has a seating surface intersecting with the rotation direction of the work material and a binding side surface inclined with respect to the seating surface. A screw hole into which a screw 75 described later is screwed is provided on the seating surface.

The coated tool 1 is located in the pocket 73 of the holder 70, and is mounted on the holder 70 by the screw 75. That is, the screw 75 is inserted into the through hole 5 of the coated tool 1, and the tip end of the screw 75 is inserted into the screw hole formed in the seating surface of the pocket 73, and the screw portions are screwed together. Thus, the coated tool 1 is mounted on the holder 70 such that the cutting edge portion protrudes outward from the holder 70.

In the embodiment, a cutting tool used for so-called turning processing is exemplified. Examples of the turning processing include boring, external turning, and groove-forming. Note that, a cutting tool is not limited to those used in the turning processing. For example, the coated tool 1 may be used as a cutting tool used for milling processing. Examples of the cutting tool used for milling processing may include milling cutters such as a plain milling cutter, a face milling cutter, a side milling cutter, and a groove milling cutter, and end mills such as a single-blade end mill, a multi-blade end mill, a taper-blade end mill, and a ball end mill.

### EXAMPLE

An example of the present disclosure will be specifically described below. The present disclosure is not limited to the following example.

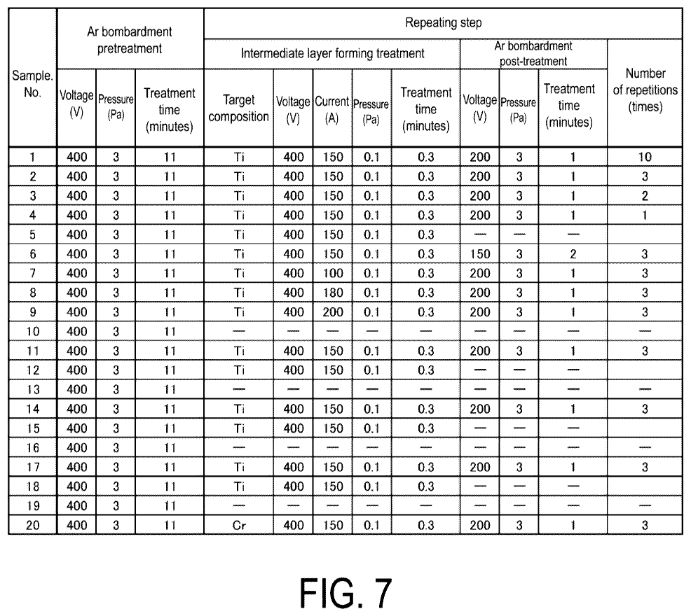

Samples No. 1 to No. 20 each having a coating layer on a base body made of a WC-based cemented carbide were fabricated. The fabrication conditions of the intermediate layers included in Samples No. 1 to No. 20 are as shown in FIG. 7. Note that among Samples No. 1 to No. 20, Samples No. 1 to No. 4, No. 6 to No. 9, No. 11, No. 14, and No. 17 correspond to Examples of the present disclosure, and Samples No. 5, No. 10, No. 12, No. 13, No. 15, No. 16, and No. 18 to No. 20 correspond to Comparative Examples. The “number of repetitions” shown in FIG. 7 is the number of repetitions of one set of the intermediate layer forming treatment and the Ar bombardment post-treatment.

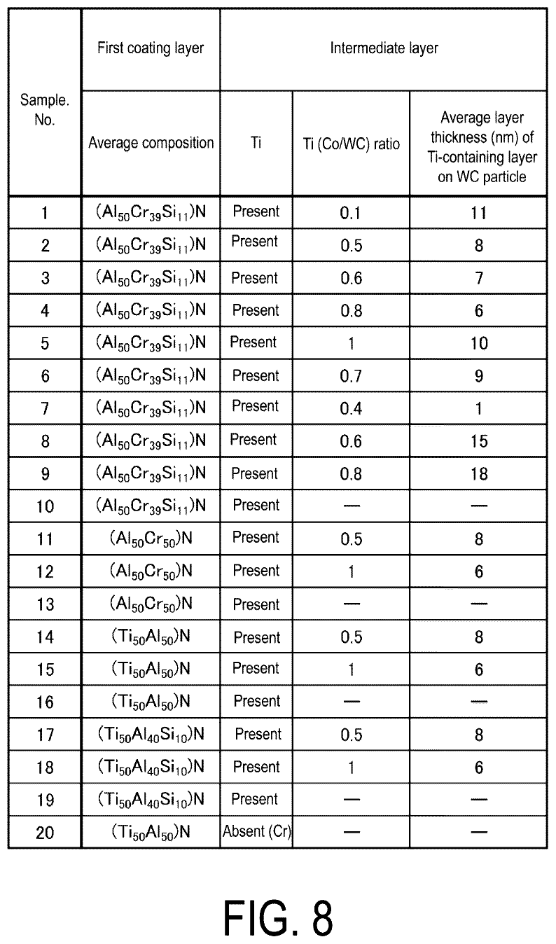

FIG. 8 a table summarizing an average composition of the first coating layer, the presence or absence of Ti in the intermediate layer, a Ti(Co/WC) ratio, and an average layer thickness of a Ti-containing layer on WC particles of Samples No. 1 to No. 20.

As illustrated in FIG. 8, the first coating layer included in each of Samples No. 1 to No. 10 is an AlCrSiN layer. Specifically, the average composition of the first coating layer included in each of Samples No. 1 to No. 10 was (Al₅₀Cr₃₉ Sin₁₁)N. The first coating layer included in each of Samples No. 11 to No. 13 is an AlCrN layer. Specifically, the average composition of the first coating layer included in each of Samples No. 11 to No. 13 was (Al₅₀Cr₅₀)N. The first coating layer included in each of Samples No. 14 to No. 16 and No. 20 is a TiAIN layer. Specifically, the average composition of the first coating layer included in each of Samples No. 14 to No. 16 and No. 20 was (Ti₅₀Al₅₀)N. The first coating layer included in each of samples No. 17 to No. 19 is a TiAlSiN layer. Specifically, the average composition of the first coating layer included in each of Samples No. 17 to No. 19 was (Ti₅₀Al₄₀Si₁₀)N.

Among Samples No. 1 to No. 20, Samples No. 1 to No. 9, No. 11, No. 12, No. 14, No. 15, No. 17, and No. 18 each have an intermediate layer containing Ti. On the other hand, Samples No. 10, No. 13, No. 16, and No. 19 do not have an intermediate layer. Sample No. 20 does not have an intermediate layer containing Ti but has an intermediate layer containing Cr.

Regarding Samples No. 1 to No. 9, No. 11, No. 12, No. 14, No. 15, No. 17, and No. 18 each having the intermediate layer containing Ti, the Ti(Co/WC) ratio was 0.1 in Sample No. 1, 0.5 in Sample No. 2, 0.6 in Sample No. 3, 0.8 in Sample No. 4, 1 in Sample No. 5, 0.7 in Sample No. 6, 0.6 in Sample No. 8, 0.8 in Sample No. 9, 0.5 in Sample No. 11, 1 in Sample No. 12, 0.5 in Sample No. 14, 1 in Sample No. 15, 0.5 in Sample No. 17, and 1 in Sample No. 18. The average layer thickness of the Ti-containing layer on the WC particles was 11 nm in Sample No. 1, 8 nm in Sample No. 2, 7 nm in Sample No. 3, 6 nm in Sample No. 4, 10 nm in Sample No. 5, 9 nm in Sample No. 6, 15 nm in Sample No. 8, 18 nm in Sample No. 9, 8 nm in Sample No. 11, 6 nm in Sample No. 12, 8 nm in Sample No. 14, 6 nm in Sample No. 15, 8 nm in Sample No. 17, and 6 nm in Sample No. 18.

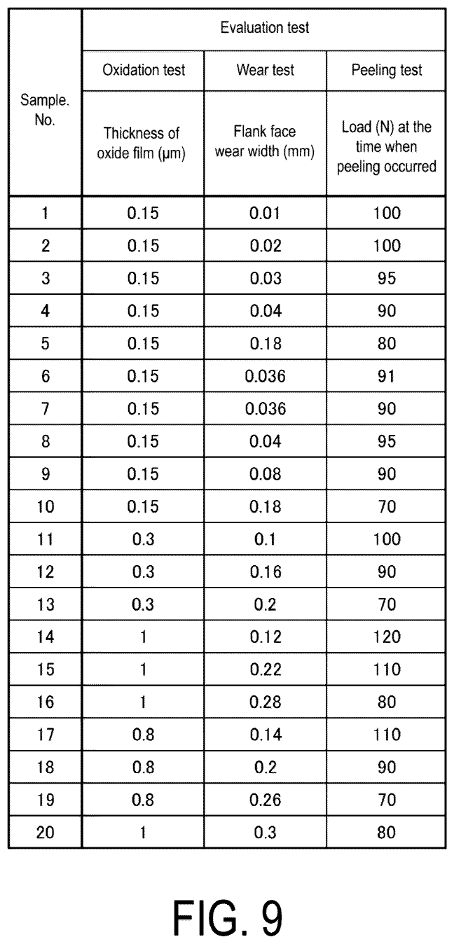

FIG. 9 is a table summarizing results of an oxidation test, a wear test, and a peeling test on Samples No. 1 to No. 20. The test conditions of the oxidation test, the wear test and the peeling test are as follows.

### Oxidation Test

The AlCr-based coating films of Samples No. 1 to No. 13 were subjected to an oxidation test in which after a predetermined intermediate layer forming treatment was performed on a platinum wire, the coating film was formed to have a thickness of 3 um, and the obtained coated platinum wire was held in the air at 1000°° C. for 1 hour. The Ti-based coating films of Samples No. 14 to No. 20 were subjected to an oxidation test in which after a predetermined intermediate layer forming treatment was performed on a platinum wire, the coating film was formed to have a thickness of 3 um, and the obtained coated platinum wire was held in the air at 800° C. for 1 hour.

The platinum wire after the test was subjected to cross-sectional processing, and the thickness of the oxide film was observed by observing the film state from the cross-section. Note that the smaller the thickness of the oxide film, the better the oxidation resistance.

Wear Test

The wear test was performed under the following conditions using a double-edged cemented carbide ball endmill (model number: 2KMBL0200-0800-S4).
(1) Cutting method: pocket machining
(2) Work material: SKD11H
(3) Feed fz: 1320 mm/min
(4) Cutting amount: ap 0.08 mm×ae 0.20 mm
(5) Evaluation Method: Flank side face wear after 20 m machining was measured with a microscope.

Peeling Test

The peeling test was performed with a scratch tester. The load range was set to 20 to 150 N, and the evaluation was performed with the load at the time when peeling occurred.

As shown in FIG. 9, Samples No. 1 to No. 4, No. 6 to No. 9, No. 11, No. 14, and No. 17 having the intermediate layer containing Ti and having the Ti(Co/WC) ratio of 0.8 or less exhibited high adhesion of the coating film and high wear resistance, as compared with the samples having the Ti(Co/WC) ratio of greater than 0.8. In particular, Samples No. 1 to No. 4 and No. 6 to No. 9 in which the average layer thickness of the Ti-containing layer on the WC particles was 15 nm or less and the average composition of the first coating layer was (Al₅₀Cr₄₀Si₁₀)N were excellent in terms of oxidation resistance, wear resistance, and adhesion to the coating.

EDX Surface Analysis

Sample No. 2 was subjected to surface analysis by EDX analysis (energy dispersive X-ray analysis). The analysis conditions are as follows.
(1) Sample pretreatment: thinning by FIB method (μ-sampling method)
(2) Elemental analysis (surface analysis)
(3) Scanning transmission electron microscope: JEM-ARM200F manufactured by JEOL Ltd.
(4) Acceleration voltage: 200 kV
(5) Beam diameter: about 0.2 nmo
(6) Elemental analyzer: JED-2300T
(7) X-ray detector: Si drift detector
(8) Energy resolution: about 140 eV
(9) X-ray take-off angle: 21.9° (10) Solid angle: 0.98 sr
(11) Number of captured pixels: 256× 256

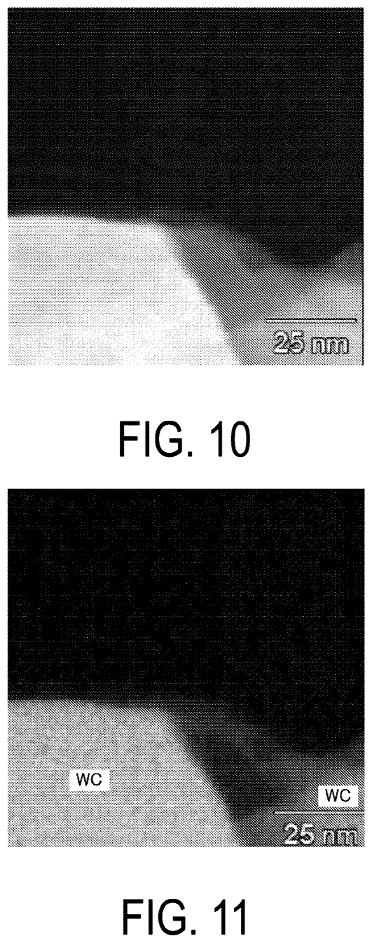

FIG. 10 is a scanning transmission electron microscope image of the coated tool according to an example. Specifically, FIG. 10 illustrates a scanning transmission electron microscope image (HAADF-STEM image) of an interface region between the base body and the first coating layer in a cross section perpendicular to the surface of the base body.

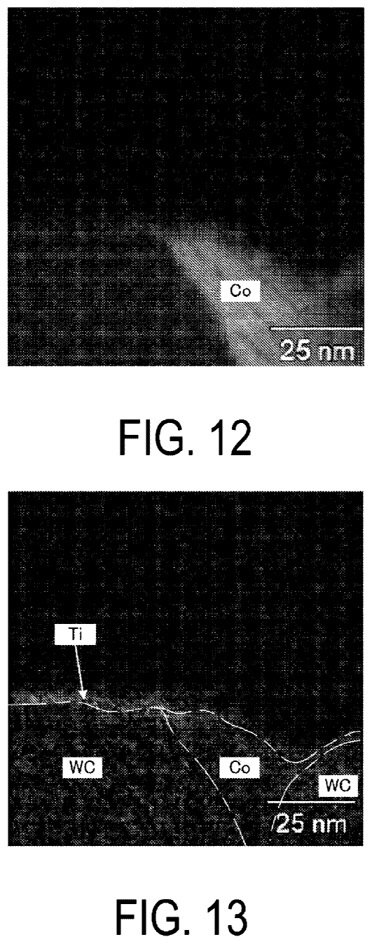

FIGS. 11 to 13 illustrate element mapping images in the same region as the scanning transmission electron microscope image shown in FIG. 10. Specifically, FIG. 11 is a WC mapping image of the coated tool according to the example, FIG. 12 is a Co mapping image of the coated tool according to the example, and FIG. 13 is a Ti mapping image of the coated tool according to the example.

As illustrated in FIGS. 11 to 13, in the coated tool according to the example, Ti located in the interface region between the base body and the first coating layer is located mostly on WC among WC and Co contained in the base body.

As illustrated in FIG. 12, in the coated tool according to the example, at least a portion of the binding phase containing Co is in contact with the first coating layer.

Line Extraction of EDX Analysis Data

For the sample manufactured by the above-described manufacturing method, a range on a transverse line from the first coating layer to the WC particles (hereinafter referred to as “extraction range on WC”) and a range on a transverse line from the first coating layer to the binding phase (hereinafter referred to as “extraction range on Co”) were extracted from the EDX analysis data (surface analysis data), respectively, and the amount of Ti was measured for each extraction range. The analysis conditions of the extracted EDX analysis data are the same as the analysis conditions of the surface analysis described above.

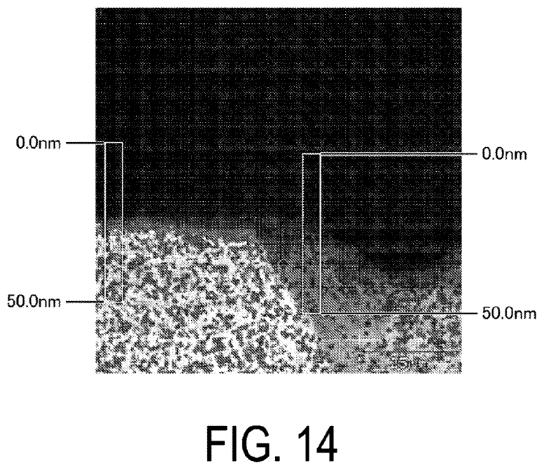

FIG. 14 is a view illustrating an extraction range on WC and an extraction range on Co. As illustrated in FIG. 14, a region having a length of 50.0 nm along a transverse direction from the first coating layer to the WC particle was defined as an extraction range on WC. The origin (0.0 nm) of the extraction range on WC is located in the first coating layer and the end point (50.0 nm) is located in the WC particle.

A range having a length of 50.0 nm along a transverse direction from the first coating layer to the binding phase containing Co was defined as an extraction range on Co. The origin (0.0 nm) of the extraction range on Co is located in the first coating layer and the end point (50.0 nm) is located in the binding phase.

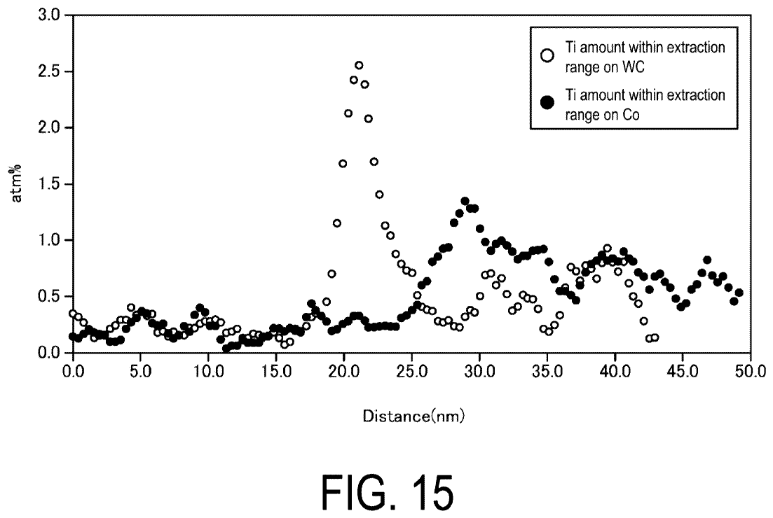

FIG. 15 is a graph showing measurement results of amounts of Ti within the extraction range on WC and the extraction range on Co. In FIG. 15, the amount of Ti measured within the extraction range on WC is indicated by a white circle, and the amount of Ti measured within the extraction range on Co is indicated by a black circle.

Here, a maximum value of the Ti amount (atm %) obtained by elemental analysis of the extraction range on WC is defined as a Ti(WC) value, and a maximum value of the Ti amount (atm %) obtained by elemental analysis of the extraction range on Co is defined as a Ti(Co) value. As shown in FIG. 15, the Ti(WC) value was about 2.55 atm %, and the Ti(Co) value was 1.35 atm %. The ratio (Ti(Co) value/Ti(WC) value) of the Ti(WC) value and the Ti(Co) value was about 0.53.

As such, in the coated tool according to the example, the ratio (Ti(Co/WC) ratio) of the Ti(WC) value and the Ti(Co) value is 0.8 or less.

As described above, a coated tool (as an example, the coated tool 1) according to an embodiment includes a base body (as an example, the base body 10) made of a WC-based cemented carbide containing WC particles (as an example, the WC particles 10a) as a hard phase component and Co as the main component of a binding phase (as an example, the binding phase 10b), and a first coating layer (as an example, the first coating layer 23) located on the base body. The first coating layer is made of at least one element selected from the group consisting of Al, Cr, Si, Group 4 elements, Group 5 elements, and Group 6 elements, and at least one element selected from the group consisting of C and N. In an interface region between the base body and the first coating layer in a cross section perpendicular to a surface of the base body, when a maximum value (atm %) of Ti obtained by elemental analysis in a transverse direction from the first coating layer to the WC particle is defined as a Ti(WC) value, a maximum value (atm %) of Ti obtained by elemental analysis in a transverse direction from the first coating layer to the binding phase is defined as a Ti(Co) value, and a ratio of the Ti(WC) value and the Ti (Co) value (Ti(Co) value/Ti(WC) value) is defined as a Ti(Co/WC) ratio, the Ti(Co/WC) ratio is 0.8 or less.

Therefore, the coated tool according to the embodiment can enhance adhesion between the coating layer and the base body.

Note that the shape of the coated tool 1 illustrated in FIG. 1 is merely an example and does not limit the shape of the coated tool according to the present disclosure. The coated tool according to the present disclosure may include a body having, for example, a rotation axis and a rod-like shape extending from a first end toward a second end, a cutting edge located at the first end of the body, and a groove extending in a spiral shape from the cutting edge toward the second end of the body.

Further effects and variations can be readily derived by those skilled in the art. Thus, a wide variety of aspects of the present invention are not limited to the specific details and a representative embodiment represented and described above. Accordingly, various changes are possible without departing from the spirit or scope of the general inventive concepts defined by the appended claims and their equivalents.

1. A coated tool comprising:
a base body made of WC-based cemented carbide containing WC particles as a hard phase component and Co as a main component of a binding phase, and
a first coating layer located on the base body, wherein
the first coating layer is made of at least one element selected from the group consisting of Al, Cr, Si, Group 4 elements, Group 5 elements, and Group 6 elements, and at least one element selected from the group consisting of C and N, and
in an interface region between the base body and the first coating layer in a cross section perpendicular to a surface of the base body, when a maximum value (atm %) of Ti obtained by elemental analysis in a transverse direction from the first coating layer to the WC particle is defined as a Ti(WC) value, a maximum value (atm %) of Ti obtained by elemental analysis in a transverse direction from the first coating layer to the binding phase is defined as a Ti(Co) value, and a ratio of the Ti(WC) value and the Ti (Co) value (Ti(Co) value/Ti(WC) value) is defined as a Ti(Co/WC) ratio, the Ti(Co/WC) ratio is 0.8 or less.

2. The coated tool according to claim 1, wherein
a thickness of a region containing Ti on the WC particle in the interface region is 1 nm or greater and 15 nm or less.

3. A cutting tool comprising:
a rod-like holder comprising a pocket at an end portion thereof; and
the coated tool according to claim 1 located in the pocket.
